(19) United States
(12) Patent Application Publication
(10) Pub. No.: US 2025/0305113 A1
(43) Pub. Date: Oct. 2, 2025

(54) OXIDE TARGET MATERIAL AND PREPARATION METHOD THEREOF

(71) Applicant: SOUTH CHINA UNIVERSITY OF TECHNOLOGY, Guangzhou (CN)

(72) Inventors: Miao XU, Guangzhou (CN); Hua XU, Guangzhou (CN); Min LI, Guangzhou (CN); Hong TAO, Guangzhou (CN); Jianhua ZOU, Guangzhou, (CN); Lei WANG, Guangzhou (CN); Junbiao PENG, Guangzhou (CN)

(21) Appl. No.: 19/234,394

(22) Filed: Jun. 11, 2025

Related U.S. Application Data
(63) Continuation of application No. PCT/CN2023/127907, filed on Oct. 30, 2023.

(30) Foreign Application Priority Data
Dec. 16, 2022 (CN) 2022116368910

(51) Int. Cl. C23C 14/34

(52) U.S. Cl. CPC C23C 14/3414

(57) ABSTRACT

The present disclosure to an oxide target material and a preparation method thereof. The oxide target material includes an oxide of an element A, an oxide of an element B, an oxide of an element R, and an oxide of an element M, wherein the element A is indium; the element B is selected from the group consisting of gallium, zinc, and tin, or a combination of two or more thereof; the element R is selected from the group consisting of cerium, praseodymium, ytterbium, dysprosium, and terbium, or a combination of two or more thereof; and the element M is selected from the group consisting of scandium, silicon, titanium, tantalum, germanium, and antimony, or a combination of two or more thereof. The present disclosure refines a grain size of the oxide target material by introducing the oxide of the element M into the oxide target material.

### CROSS-REFERENCE TO RELATED APPLICATIONS

This application is a continuation of International Application No. PCT/CN2023/127907, filed on Oct. 30, 2023, which claims priority to Chinese Patent Application No. 202211636891.0, filed on Dec. 16, 2022. All of the aforementioned applications are incorporated herein by reference in their entireties.

### TECHNICAL FIELD

The present disclosure relates to the technical field of semiconductor materials, in particular to an oxide target material and a preparation method thereof.

### BACKGROUND

With the increasing market competitiveness in China's new display industry in recent years, as the world's largest display panel production base of thin film transistor-liquid crystal displays (TFT-LCDs), oxide target materials have also become a research hotspot in China. Thin films obtained by sputtering ZnO, IZO, IGZO and other target materials can be used as active layers of TFT, and have attracted great attention from researchers and industry professionals for their excellent performance in flat panel display (FPD) applications such as an LCD, an organic light emitting diode (OLED), and electronic paper.

Various electrical and optical properties of sputtered thin films are affected by the density, grain size, composition and microstructure uniformity of oxide target materials. In order to improve the quality of the oxide target materials and make them meet the demands of the high-end display panel industry, many researchers have improved and upgraded the powder raw materials of the oxide target materials. For example, Chinese Patent CN107146816A discloses an oxide semiconductor thin film and a thin film transistor prepared therefrom, which improves the optical stability of oxide thin film transistor devices by doping rare earth oxides.

However, due to the larger ionic radii of rare earth elements compared to In³⁺, Zn²⁺, Ga³⁺, and Sn⁴⁺ in host oxides, and the fact that a rare earth oxide Ln₂O₃ is usually in a hexagonal crystal system, with a metal ion coordination number of seven, six oxygen atoms occupy the six corners of an octahedron, and the seventh oxygen atom is located in the center of one face of the octahedron. This differs significantly from the bixbyite structure of a cubic crystal system of In₂O₃, the corundum structure of Ga₂O₃, the sphalerite or wurtzite structure of ZnO, and the rutile structure of SnO₂, which makes it difficult to achieve substitutional doping of rare earth oxides in target materials. During a sintering process, doped rare earth elements will accumulate at grain boundaries, leading to the deviation of material composition in micro-regions. In addition, the grain size of an IGZO target material that have already been mass-produced is usually 10-30 μm, which is too large, making it easier for doped elements to be excessively concentrated at limited grain boundaries, and resulting in cracking of oxide target materials.

### SUMMARY

In view of this, it is necessary to provide an oxide target material and a preparation method thereof to solve the above problems. The prepared oxide target material is high in density, small in grain size, and uniform in element distribution and microstructure.

To achieve the above objective, the present disclosure adopts the following technical solutions.

In the first aspect, the present disclosure provides an oxide target material, including an oxide of an element A, an oxide of an element B, an oxide of an element R, and an oxide of an element M;
the element A is indium;
the element B is selected from the group consisting of gallium, zinc, and tin, or a combination of two or more thereof;
the element R is selected from the group consisting of cerium, praseodymium, ytterbium, dysprosium, and terbium, or a combination of two or more thereof; and
the element M is selected from the group consisting of scandium, silicon, titanium, tantalum, germanium, and antimony, or a combination of two or more thereof.

Further, in the above-mentioned oxide target material, atomic molar ratios of the elements A, B, R and M in the oxide target material are x, y, z and m, respectively, where 0.6≤x≤0.9994, 0≤y≤0.3994, 0.0005≤z≤0.05, 0.001≤m≤0.02, and x+y+z+m=1.

Further, in the above-mentioned oxide target material, 0.76≤x≤0.9994, and 0.005≤m≤0.015.

Further, in the above-mentioned oxide target material, a resistivity of the oxide target material is less than 10 Ω·cm.

Further, in the above-mentioned oxide target material, a relative density of the oxide target material is 98.5% or more.

Further, in the above-mentioned oxide target material, oxide target material grains have a maximum grain size of less than 8 μm.

Further, in the above-mentioned oxide target material, the oxide target material grains have sizes of 3-5 μm.

In the second aspect, the present disclosure provides a preparation method of the above-mentioned oxide target material, including following steps:
step 1: pressing powders into a target material blank;
step 2: drying the target material blank and then performing debinding treatment;
step 3: continuing to heat the debinded target material blank up to a first sintering temperature at a first heating rate in a gas environment for sintering, then continuing to heat the debinded target material blank up to a second sintering temperature at a second heating rate for sintering, and finally cooling down to the first sintering temperature at a first cooling rate to continue sintering;
step 4: after sintering is completed, cooling down to a room temperature at a second cooling rate in the gas environment to obtain a sintered target material; and
step 5: machining and bonding the sintered target material.

Further, according to the above-mentioned preparation method of the oxide target material, in the powders, a mean grain size of the oxide of the element A is 0.05-0.5 μm, a mean grain size of the oxide of the element B is 0.05-0.5 μm, a mean grain size of the oxide of the element R is 0.05-1.5 μm, and a mean grain size of the oxide of the element M is 0.05-1.5 μm.

Further, according to the above-mentioned preparation method of the oxide target material, step 1 specifically includes:
step 1.1: mixing the powders in proportion, adding a dispersing agent, water and a binder, and grinding to obtain a paste;
step 1.2: carrying out spray granulation on the paste, drying, and then screening the granulated powder with grain sizes of D₅₀=1.50-2.75 μm, D₁₀≥1.0 μm, and D₉₀≤3.5 μm, where a grain size distribution coefficient P=(D₉₀-D₁₀)/D₅₀≤2.0; and
step 1.3: carrying out mould pressing on the screened powder to obtain the target material blank.

Preferably, in step 1.1, the oxide of the element A, the oxide of the element B, the dispersing agent and the water are first mixed and ground into a paste I; then, the oxide of the element R, the oxide of the element M, the dispersing agent and the water are mixed and ground into a paste II; and finally, the paste I, the paste II and the binder are mixed and ground.

Preferably, in step 1.1, the oxide of the element R, the oxide of the element M, the dispersing agent and the water are first mixed and ground into a paste I; the oxide of the element A and the oxide of the element B are sequentially added to the paste I, with the dispersing agent and the water being correspondingly added after each of the oxides is added, and the resulting mixture is ground into a paste II; and finally, the binder is added to the paste II to continue grinding.

Preferably, ultrasonic or vacuum defoaming may be additionally performed during the paste preparation process.

More preferably, a mass percentage of the dispersing agent is 0.1-2.0%, and a mass percentage of the binder is 0.1-1.5%; and grinding is carried out using a sand mill, with a mass percentage of a ball milling medium being 40-60%. The mass percentage refers to a proportion of the mass of each substance to the total mass.

Preferably, in step 1.2, a granulation temperature is 180-200° C., and a feed rate is 5-20 rpm.

Preferably, the mould pressing in step 1.3 is performed in presence of an oil hydraulic press, with a pressure of 20-100 MPa and a holding time of 2-15 min.

More preferably, the target material blank obtained after the mould pressing in step 1.3 is covered with a flexible mold and further pressed by means of isostatic pressing; and a pressure for the isostatic pressing is 220-300 MPa, and the isostatic pressing lasts for 10-30 min.

Further, the debinding treatment in step 2 comprises raising a temperature of the target material blank to 600-800° C. at a heating rate of 0.2-1° C./min; and debinding lasts for 50-100 h.

Preferably, the heating rate is 0.5° C./min. If the heating rate is too fast, it will cause oil to evaporate at a constant rate or not completely evaporate, which will easily cause pores or cracks, thus affecting the quality of the target material.

Further, the gas environment in step 3 includes one or a mixture of two or more of air, water vapor, nitrogen, oxygen, ozone, and nitrous oxide, where a certain amount of oxidizing gas can keep the oxide of the element R in a high valence state, thereby better exerting the effect of a light stabilizer and facilitating the acquisition of the target material with a uniform color. In addition, injecting a certain amount of water vapor into the gas environment is conducive to rapid cooling.

Further, the gas environment in different sintering processes described in step 3 and the gas environment described in step 4 are the same or different.

Further, the first heating rate is 0.1-5° C./min, preferably 0.1-2.5° C./min; and the first sintering temperature is 1200-1400° C.

Further, the second heating rate is 5-10° C./min, and the second sintering temperature is 1410-1600° C.

Further, the sintering process of step 3 is repeated for a plurality of times, and the first sintering temperature, the second sintering temperature, the first heating rate, the second heating rate and the first cooling rate are the same or different during the repeated processes. By repeating the sintering process of step 3 for a plurality of times, a crystal phase structure can be controlled, and the prepared oxide target material has a smaller grain size.

Further, each holding time at the first sintering temperature is 50-250 h; and each holding time at the second sintering temperature is 10-60 min.

Further, the first cooling rate is 1-10° C./min.

Further, the second cooling rate in step 4 is 1-5° C./min.

The beneficial effects of the present disclosure are:
(1) The present disclosure refines a grain size of the oxide target material by introducing the oxide of the element M into the oxide target material, so that the relative density of the oxide target material is higher, and the element distribution and microstructure thereof are more uniform.
(2) The first sintering temperature and the second sintering temperature are set in the preparation and sintering process of the oxide target material provided by the present disclosure, the temperature is quickly raised from the first sintering temperature to the second sintering temperature, and the second sintering temperature is kept for a short time, so that the growth of crystal grains is inhibited. Then, the temperature is lowered to the first sintering temperature to perform low-temperature sintering for a long time, thereby obtaining a fully dense oxide target material. In addition, the present disclosure can achieve the effect of controlling the crystal phase structure by repeating the above sintering process for a plurality of times, so that the oxide target material is smaller in grain size and uniform in microstructure.

### BRIEF DESCRIPTION OF THE DRA WINGS

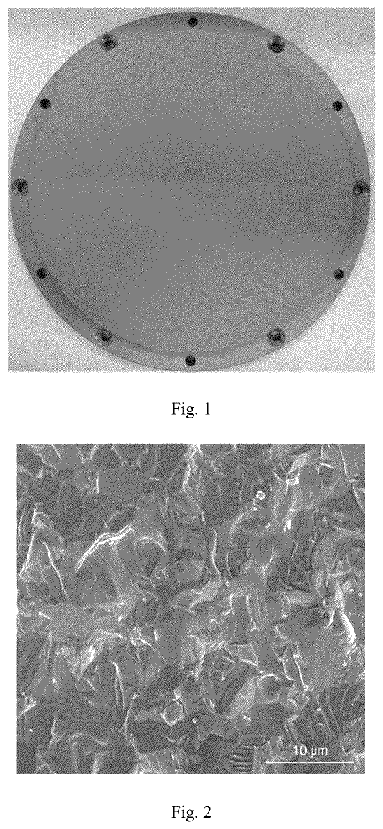

FIG. 1 is an external view of an oxide target material provided in Embodiment 7.

FIG. 2 is a scanning electron microscopy (SEM) image of the oxide target material provided in Embodiment 7.

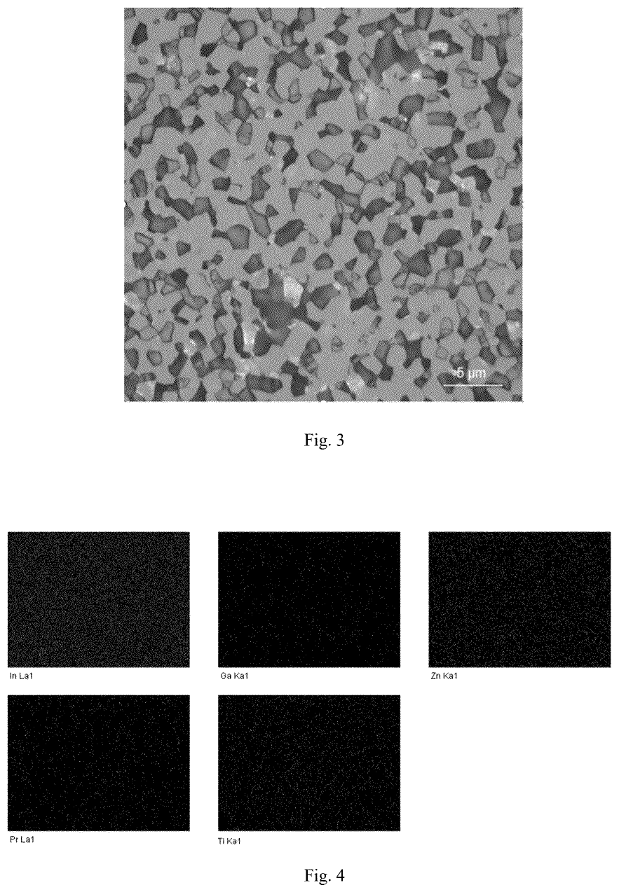

FIG. 3 is a grain size diagram of the oxide target material provided in Embodiment 7.

FIG. 4 shows distribution diagrams of metal elements of the oxide target material provided in Embodiment 7.

### DETAILED DESCRIPTION OF THE EMBODIMENTS

In order to make the objectives, technical solutions, and advantages of the present disclosure clearer, the technical solutions of the present disclosure will be described clearly and completely hereinafter with reference to embodiments of the present disclosure. It should be noted that the described embodiments are only a part rather than all of the embodiments of the present disclosure. Based on the embodiments of the present disclosure, all other embodiments obtained by those of ordinary skill in the art without making creative efforts shall fall within the protection scope of the present disclosure.

In the description of the present disclosure, it should be noted that if the specific conditions are not specified in the embodiments, the conventional conditions or the conditions recommended by manufacturers shall be followed. If manufacturers are not indicated on reagents or instruments used, they are all conventional products that can be purchased from the market.

In the powders used in the embodiments of the present disclosure, a mean grain size of an oxide of an element A was 0.05-0.5 μm, a mean grain size of an oxide of an element B was 0.05-0.5 μm, a mean grain size of an oxide of an element R was 0.05-1.5 μm, and a mean grain size of an oxide of an element M was 0.05-1.5 μm.

### Embodiment 1

An oxide target material includes an oxide of an element A, an oxide of an element B, an oxide of an element R, and an oxide of an element M;
the element A is indium (In);
the element B includes gallium (ga) and zinc (Zn); a molar ratio of gallium to zinc is 1:2;
the element R is cerium (Ce);
the element M is scandium (Sc); and
in the above-mentioned oxide target material, atomic molar ratios of the elements A, B, R and M in the oxide target material are x, y, z and m, respectively, where x=0.65, y=0.33, z=0.005, and m=0.015.

That is, a molar ratio of metal atoms in the target material satisfies In:Ga:Zn:Ce:Sc=0.65:0.11:0.22:0.005:0.015.

The above oxide target material was prepared using a following method.

Step 1: Powders were pressed into a target material blank.

Step 1.1: First, oxide powders of the elements A, B, R and M were weighed according to the above molar ratios of the metal atoms in the target material, with a total weight of 6 kg. The oxide of the element A and the oxide powder of the element B were premixed with a certain amount of polyvinyl pyrrolidone and a certain amount of pure water, where the polyvinyl pyrrolidone accounted for 1.2% of a total mass of a mixture obtained after mixing, and a solid content of the premixed mixture was 50%. The resulting mixture was ultrasonically pre-dispersed for 30 min, and ground into a paste I with a sand mill rotating at a speed of 800 rpm, with a grinding time of 20 h. A mean grain size of the mixed powder in the paste I was less than 0.8 μm. Vacuum defoaming was carried out on resulting paste I.

Then, the oxide of the element R and the oxide of the element M were premixed with polyvinyl pyrrolidone and a certain amount of pure water, where the polyvinyl pyrrolidone accounted for 1.2% of a total mass of a mixture obtained after mixing, and a solid content of the premixed mixture was 50%. The resulting mixture was ultrasonically pre-dispersed for 30 min, and ground into a paste II with a sand mill rotating at a speed of 800 rpm, with a grinding time of 20 h. A mean grain size of the mixed powder in the paste II was less than 0.8 μm. Vacuum defoaming was carried out on the resulting paste II.

Finally, the paste I, the paste II, polyvinyl alcohol and polyethylene glycol were mixed, where each of contents of the polyvinyl alcohol and the polyethylene glycol accounted for 1.2% of a total mass of a mixture obtained after mixing, and a solid content of the mixed paste was 42%. Grinding was performed for 5 h with a sand mill, and a mean grain size of the mixed powder in the final paste was less than 0.8 μm. Vacuum defoaming was carried out on the resulting paste.

Step 1.2: Spray granulation was carried out on the paste obtained after the treatment described in step 1.1, with a granulation temperature of 200° C. and a feed rate of 10 rpm. The granulated powder was dried, and then screened to obtain the powder with grain sizes of D₅₀=1.6 μm, D₁₀≥1.0 μm, and D₉₀≤3.0 μm, where a grain size distribution coefficient P=(D₉₀−D₁₀)/D₅₀=1.0.

Step 1.3: Mould pressing was carried out on the screened powder in presence of an oil hydraulic press, with a pressure of 80 MPa and a holding time of 5 min. After that, the resulting powder was further pressed by means of isostatic pressing under a pressure of 280 MPa, and the isostatic pressing lasted for 30 min.

Step 2: The target material blank was dried and then debinded. Specifically, the target material blank was first heated up to 700° C. at a heating rate of 0.5° C./min, and debinding lasted for 60 h.

Step 3: The temperature was raised from 700° C. to a first sintering temperature of 1250° C. at a first heating rate of 1° C./min, and the first sintering temperature was kept unchanged for 10 h in a gas environment with an oxygen content of 20-30% in the air. Then, the temperature was raised to a second sintering temperature of 1420° C. at a second heating rate of 8° C./min, and the second sintering temperature was kept unchanged for 30 min in a gas environment with an oxygen content of 40-50% in the air. After that, the temperature was lowered to the first sintering temperature of 1250° C. at a first cooling rate of 3° C./min, and the first sintering temperature was kept unchanged for 10 h in the gas environment with the oxygen content of 40-50% in the air.

The temperature was rapidly raised to a second sintering temperature of 1460° C. at the heating rate of 8° C./min, and the second sintering temperature was kept unchanged for 30 min in a gas environment with an oxygen content of 60-70% in the air; and then, the temperature was lowered to the first sintering temperature of 1250° C. at the cooling rate of 3° C./min, and the first sintering temperature was kept unchanged for 10 h in the gas environment with the oxygen content of 40-50% in the air.

The temperature was rapidly raised to a second sintering temperature of 1500° C. at the heating rate of 8° C./min, and the second sintering temperature was kept unchanged for 30 min in the gas environment with an oxygen content of 60-70% in the air; and then, the temperature was lowered to the first sintering temperature of 1250° C. at the cooling rate of 3° C./min, and the first sintering temperature was kept unchanged for 10 h in the gas environment with the oxygen content of 40-50% in the air.

Step 4: The temperature was lowered to a room temperature at a second cooling rate of 1° C./min in the gas environment with the oxygen content of 20-30% in the air to obtain a sintered target material.

Step 5: The obtained sintered target material was machined and then bonded to a metal backing plate using an indium bonding method.

### Embodiment 2

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is praseodymium (Pr);
the element M is titanium (Ti); and
in the above-mentioned oxide target material, atomic molar ratios of the elements A, B, R and M in the oxide target material are x, y, z and m, respectively, where x=0.64, y=0.33, z=0.015, and m=0.015.

In a preparation method of the oxide target material, powders of indium oxide (In₂O₃), gallium oxide (Ga₂O₃), zinc oxide (ZnO), praseodymium oxide (Pr₆O₁₁), and titanium oxide (TiO₂) were respectively weighed according to an atomic molar ratio of In:Ga:Zn:Pr:Ti=0.64:0.11:0.22:0.015:0.015, with a total powder weight of 6 kg. The rest steps were the same as those described in the preparation method of Embodiment 1.

### Embodiment 3

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is ytterbium (Yb);
the element M is silicon (Si); and
in the above-mentioned oxide target material, atomic molar ratios of the elements A, B, R and M in the oxide target material are x, y, z and m, respectively, where x=0.64, y=0.33, z=0.029, and m=0.001.

In a preparation method of the oxide target material, powders of indium oxide (In₂O₃), gallium oxide (Ga₂O₃), zinc oxide (ZnO), ytterbium oxide (Yb₂O₃), and silicon dioxide (SiO₂) were respectively weighed according to an atomic molar ratio of In:Ga:Zn:Yb:Si=0.64:0.11:0.22:0.029:0.001, with a total powder weight of 6 kg. The rest steps were the same as those described in the preparation method of Embodiment 1.

### Embodiment 4

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is dysprosium (Dy);
the element M is tantalum (Ta); and
in the above-mentioned oxide target material, atomic molar ratios of the elements A, B, R and M in the oxide target material are x, y, z and m, respectively, where x=0.64, y=0.33, z=0.025, and m=0.005.

In a preparation method of the oxide target material, powders of indium oxide (In₂O₃), gallium oxide (Ga₂O₃), zinc oxide (ZnO), dysprosium oxide (Dy₂O₃), and tantalum oxide (Ta₂O₅) were respectively weighed according to an atomic molar ratio of In:Ga:Zn:Dy:Ta=0.64:0.11:0.22:0.025:0.005, with a total powder weight of 6 kg. The rest steps were the same as those described in the preparation method of Embodiment 1.

### Embodiment 5

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is praseodymium (Pr);
the element M is germanium (Ge); and
in the above-mentioned oxide target material, atomic molar ratios of the elements A, B, R and M in the oxide target material are x, y, z and m, respectively, where x=0.64, y=0.33, z=0.015, and m=0.015.

In a preparation method of the oxide target material, powders of indium oxide (In₂O₃), gallium oxide (Ga₂O₃), zinc oxide (ZnO), praseodymium oxide (Pr₆O₁₁), and germanium oxide (GeO₂) were respectively weighed according to an atomic molar ratio of In:Ga:Zn:Pr:Ge=0.64:0.11:0.22:0.015:0.015, with a total powder weight of 6 kg. The rest steps were the same as those described in the preparation method of Embodiment 1.

### Embodiment 6

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is praseodymium (Pr);
the element M is antimony (Sb); and
in the above-mentioned oxide target material, atomic molar ratios of the elements A, B, R and M in the oxide target material are x, y, z and m, respectively, where x=0.64, y=0.33, z=0.01, and m=0.02.

In a preparation method of the oxide target material, powders of indium oxide (In₂O₃), gallium oxide (Ga₂O₃), zinc oxide (ZnO), praseodymium oxide (Pr₆O₁₁), and antimony oxide (Sb₂O₃) were respectively weighed according to an atomic molar ratio of In:Ga:Zn:Pr:Sb=0.64:0.11:0.22:0.01:0.02, with a total powder weight of 6 kg. The rest steps were the same as those described in the preparation method of Embodiment 1.

### Embodiment 7

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:3;
the element R is praseodymium (Pr);
the element M is titanium (Ti); and
in the above-mentioned oxide target material, atomic molar ratios of the elements A, B, R and M in the oxide target material are x, y, z and m, respectively, where x=0.65, y=0.32, z=0.02, and m=0.01.

In a preparation method of the oxide target material, powders of indium oxide (In₂O₃), gallium oxide (Ga₂O₃), zinc oxide (ZnO), praseodymium oxide (Pr₆O₁₁), and titanium oxide (TiO₂) were respectively weighed according to an atomic molar ratio of In:Ga:Zn:Pr:Ti=0.65:0.08:0.24:0.02:0.01, with a total powder weight of 6 kg. The rest steps were the same as those described in the preparation method of Embodiment 1.

The appearance of the 6-inch circular target material prepared is shown in FIG. 1. The prepared oxide target material was characterized by a scanning electron microscope (SEM), with its porosity as shown in FIG. 2. The oxide target material exhibits a high density with only a small number of pores. A grain size of the oxide target material is shown in FIG. 3, and a mean grain size thereof is 4.1 μm. An element distribution diagram of the oxide target material is shown in FIG. 4, showing that the element distribution is uniform.

### Embodiment 8

An oxide target material includes an oxide of an element A, an oxide of an element B, an oxide of an element R, and an oxide of an element M;
the element A is indium (In);
the element B is gallium (Ga);
the element R is praseodymium (Pr);
the element M is titanium (Ti); and
in the above-mentioned oxide target material, atomic molar ratios of the elements A, B, R and M in the oxide target material are x, y, z and m, respectively, where x=0.8, y=0.18, z=0.01, and m=0.01.

In a preparation method of the oxide target material, powders of indium oxide (In₂O₃), gallium oxide (Ga₂O₃), praseodymium oxide (Pr₆O₁₁), and titanium oxide (TiO₂) were respectively weighed according to an atomic molar ratio of In:Ga:Pr:Ti=0.8:0.18:0.01:0.01, with a total powder weight of 6 kg. The rest steps were the same as those described in the preparation method of Embodiment 1.

### Embodiment 9

An oxide target material includes an oxide of an element A, an oxide of an element B, an oxide of an element R, and an oxide of an element M;
the element A is indium (In);
the element B is zinc (Zn);
the element R is praseodymium (Pr);
the element M is titanium (Ti); and
in the above-mentioned oxide target material, atomic molar ratios of the elements A, B, R and M in the oxide target material are x, y, z and m, respectively, where x=0.7, y=0.27, z=0.015, and m=0.015.

In a preparation method of the oxide target material, powders of indium oxide (In₂O₃), zinc oxide (ZnO), praseodymium oxide (Pr₆O₁₁), and titanium oxide (TiO₂) were respectively weighed according to an atomic molar ratio of In:Zn:Pr:Ti=0.7:0.27:0.015:0.015, with a total powder weight of 6 kg. The rest steps were the same as those described in the preparation method of Embodiment 1.

### Embodiment 10

An oxide target material includes an oxide of an element A, an oxide of an element B, an oxide of an element R, and an oxide of an element M;
the element A is indium (In);
the element B includes tin (Sn) and zinc (Zn); a molar ratio of tin to zinc is 1:2;
the element R is praseodymium (Pr);
the element M is titanium (Ti); and
in the above-mentioned oxide target material, atomic molar ratios of the elements A, B, R and M in the oxide target material are x, y, z and m, respectively, where x=0.61, y=0.36, z=0.01, and m=0.02.

In a preparation method of the oxide target material, powders of indium oxide (In₂O₃), tin oxide (SnO₂), zinc oxide (ZnO), praseodymium oxide (Pr₆O₁₁), and titanium oxide (TiO₂) were respectively weighed according to an atomic molar ratio of In:Sn:Zn:Pr:Ti=0.61:0.12:0.24:0.01:0.02, with a total powder weight of 6 kg. The rest steps were the same as those described in the preparation method of Embodiment 1.

### Embodiment 11

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is terbium (Tb);
the element M is antimony (Sb); and
in the above-mentioned oxide target material, atomic molar ratios of the elements A, B, R and M in the oxide target material are x, y, z and m, respectively, where x=0.62, y=0.36, z=0.005, and m=0.015.

In a preparation method of the oxide target material, powders of indium oxide (In₂O₃), gallium oxide (Ga₂O₃), zinc oxide (ZnO), terbium oxide (Tb₄O₇), and antimony oxide (Sb₂O₃) were respectively weighed according to an atomic molar ratio of In:Ga:Zn:Tb:Sb=0.62:0.12:0.24:0.005:0.015, with a total powder weight of 6 kg. The rest steps were the same as those described in the preparation method of Embodiment 1.

### Embodiment 12

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is terbium (Tb);
the element M is antimony (Sb); and
in the above-mentioned oxide target material, atomic molar ratios of the elements A, B, R and M in the oxide target material are x, y, z and m, respectively, where x=0.6, y=0.39, z=0.007, and m=0.003.

In a preparation method of the oxide target material, powders of indium oxide (In₂O₃), gallium oxide (Ga₂O₃), zinc oxide (ZnO), terbium oxide (Tb₄O₇), and antimony oxide (Sb₂O₃) were respectively weighed according to an atomic molar ratio of In:Ga:Zn:Tb:Sb=0.6:0.13:0.26:0.007:0.003, with a total powder weight of 6 kg. The rest steps were the same as those described in the preparation method of Embodiment 1.

### Embodiment 13

An oxide target material includes an oxide of an element A, an oxide of an element B, an oxide of an element R, and an oxide of an element M;
the element A is indium (In);
the element B is gallium (Ga);
the element R is terbium (Tb);
the element M is antimony (Sb); and in the above-mentioned oxide target material, atomic molar ratios of the elements A, B, R and M in the oxide target material are x, y, z and m, respectively, where x=0.9, y=0.08, z=0.01, and m=0.01.

In a preparation method of the oxide target material, powders of indium oxide (In₂O₃), gallium oxide (Ga₂O₃), terbium oxide (Tb₄O₇), and antimony oxide (Sb₂O₃) were respectively weighed according to an atomic molar ratio of In:Ga:Tb:Sb=0.9:0.08:0.01:0.01, with a total powder weight of 6 kg. The rest steps were the same as those described in the preparation method of Embodiment 1.

### Embodiment 14

An oxide target material includes an oxide of an element A, an oxide of an element B, an oxide of an element R, and an oxide of an element M;
the element A is indium (In);
the element B is zinc (Zn);
the element R is terbium (Tb);
the element M is antimony (Sb); and in the above-mentioned oxide target material, atomic molar ratios of the elements A, B, R and M in the oxide target material are x, y, z and m, respectively, where x=0.81, y=0.16, z=0.02, and m=0.01.

In a preparation method of the oxide target material, powders of indium oxide (In₂O₃), zinc oxide (Zn), terbium oxide (Tb₄O₇), and antimony oxide (Sb₂O₃) were respectively weighed according to an atomic molar ratio of In:Zn:Tb:Sb=0.81:0.16:0.02:0.01, with a total powder weight of 6 kg. The rest steps were the same as those described in the preparation method of Embodiment 1.

### Embodiment 15

An oxide target material includes an oxide of an element A, an oxide of an element B, an oxide of an element R, and an oxide of an element M;
the element A is indium (In);
the element B includes tin (Sn) and zinc (Zn); a molar ratio of tin to zinc is 1:2;
the element R is terbium (Tb);
the element M is antimony (Sb); and
in the above-mentioned oxide target material, atomic molar ratios of the elements A, B, R and M in the oxide target material are x, y, z and m, respectively, where x=0.62, y=0.36, z=0.0005, and m=0.0195.

In a preparation method of the oxide target material, powders of indium oxide (In₂O₃), tin oxide (SnO₂), zinc oxide (ZnO), terbium oxide (Tb₄O₇), and antimony oxide (Sb₂O₃) were respectively weighed according to an atomic molar ratio of In:Sn:Zn:Tb:Sb=0.62:0.13:0.26:0.0005:0.0195, with a total powder weight of 6 kg. The rest steps were the same as those described in the preparation method of Embodiment 1.

### Embodiment 16

An oxide target material includes an oxide of an element A, an oxide of an element B, an oxide of an element R, and an oxide of an element M;
the element A is indium (In);
the element B is gallium (Ga);
the element R is praseodymium (Pr);
the element M is titanium (Ti); and
in the above-mentioned oxide target material, atomic molar ratios of the elements A, B, R and M in the oxide target material are x, y, z and m, respectively, where x=0.76, y=0.21, z=0.025, and m=0.005.

That is, a molar ratio of metal atoms in the target material satisfies In:Ga:Pr:Ti=0.76:0.21:0.025:0.005.

The above oxide target material was prepared using a following method:

Step 1: Powders were pressed into a target material blank.

Step 1.1: First, oxide powders of the elements A, B, R and M were weighed according to the above ratios of the target material, with a total weight of 3 kg. The oxide of the element R, the oxide of the element M, a dispersing agent and pure water were premixed, where the dispersing agent was polyvinyl pyrrolidone, which accounted for 1.5% of a total mass of a mixture obtained after mixing, and a solid content of the premixed mixture was 45%. The resulting mixture was ultrasonically pre-dispersed for 30 min, and ground into a paste I with a sand mill rotating at a speed of 1000 rpm, with a grinding time of 10 h. A mean grain size of the mixed powder in the paste I was less than 0.8 μm. Vacuum defoaming was carried out on the resulting paste I.

Then, the oxide of the element A and the oxide of the element B were sequentially added to the paste I, and after addition of each of the oxides, polyvinyl pyrrolidone accounting for 1.5% of a total mass of a mixture obtained after mixing and an appropriate amount of pure water were added accordingly, so that a solid content of the mixture was 40%. The resulting mixture was ultrasonically pre-dispersed for 30 min, and ground into a paste II with a sand mill rotating at a speed of 1000 rpm, with a grinding time of 20 h.

Finally, polyvinyl alcohol and polyethylene glycol were added to the paste II, where each of the polyvinyl alcohol and the polyethylene glycol accounted for 1.5% of a total mass of a mixture obtained after mixing. Grinding was performed for 5 h with a sand mill, and a mean grain size of the mixed powder in the final paste was less than 0.8 μm. Vacuum defoaming was carried out on the resulting paste.

Step 1.2: Spray granulation was carried out on the paste obtained after the treatment described in step 1.1, with a granulation temperature of 180° C. and a feed rate of 10 rpm. The granulated powder was dried, and then screened to obtain the powder with a grain size of D₅₀<2 μm.

Step 1.3: Mould pressing was carried out on the screened powder in presence of an oil hydraulic press, with a pressure of 80 MPa and a holding time of 5 min. After that, the resulting powder was further pressed by means of isostatic pressing under a pressure of 300 MPa, and the isostatic pressing lasted for 20 min.

Step 2: The target material blank was dried and then debinded. Specifically, the target material blank was first heated up to 700° C. at a heating rate of 0.5° C./min, and debinding lasted for 70 h.

Step 3: The temperature was raised from 700° C. to a first sintering temperature of 1300° C. at a first heating rate of 1° C./min, and the first sintering temperature was kept unchanged for 10 h in a gas environment with an ozone content of 5-8% in the air. Then, the temperature was raised to a second sintering temperature of 1420° C. at a second heating rate of 8° C./min, and the second sintering temperature was kept unchanged for 30 min in a gas environment with an ozone content of 10-15% in the air. After that, the temperature was lowered to the first sintering temperature of 1300° C. at a first cooling rate of 3° C./min, water vapor with a flow rate of 0.1-1 L/min was replenished during the cooling process, and the first sintering temperature was kept unchanged for 10 h in the gas environment with the ozone content of 10-15% in the air.

The temperature was rapidly raised to a second sintering temperature of 1480° C. at the heating rate of 8° C./min, and the second sintering temperature was kept unchanged for 30 min in the gas environment with the ozone content of 10-15% in the air; and then, the temperature was lowered to the first sintering temperature of 1300° C. at the cooling rate of 3° C./min, water vapor with a flow rate of 0.1-1 L/min was replenished during the cooling process, and the first sintering temperature was kept unchanged for 10 h in the gas environment with the ozone content of 10-15% in the air.

Step 4: The temperature was lowered to a room temperature at a second cooling rate of 1° C./min in the gas environment with the ozone content of 10-15% in the air to obtain a sintered target material.

Step 5: The obtained sintered target material was machined and then bonded to a metal backing plate using an indium bonding method.

### Embodiment 17

An oxide target material includes an oxide of an element A, an oxide of an element R, and an oxide of an element M;
the element A is indium (In);
the element R is praseodymium (Pr);
the element M is titanium (Ti); and
in the above-mentioned oxide target material, atomic molar ratios of the elements A, R and M in the oxide target material are x, z and m, respectively, where x=0.93, z=0.05, and m=0.02.

In a preparation method of the oxide target material, powders of indium oxide (In₂O₃), praseodymium oxide (Pr₆O₁₁), and titanium oxide (TiO₂) were respectively weighed according to an atomic molar ratio of In:Pr:Ti=0.93:0.05:0.02, with a total powder weight of 3 kg. The rest steps were the same as those described in the preparation method of Embodiment 16.

### Embodiment 18

An oxide target material includes an oxide of an element A, an oxide of an element B, an oxide of an element R, and an oxide of an element M;
the element A is indium (In);
the element B is gallium (Ga);
the element R is terbium (Tb);
the element M is silicon (Si); and
in the above-mentioned oxide target material, atomic molar ratios of the elements A, B, R and M in the oxide target material are x, y, z and m, respectively, where x=0.81, y=0.17, z=0.008, and m=0.012.

In a preparation method of the oxide target material, powders of indium oxide (In₂O₃), gallium oxide (Ga₂O₃), terbium oxide (Tb₄O₇), and silicon dioxide (SiO₂) were respectively weighed according to an atomic molar ratio of In:Ga:Tb:Si=0.81:0.17:0.008:0.012, with a total powder weight of 3 kg. The rest steps were the same as those described in the preparation method of Embodiment 16.

### Embodiment 19

An oxide target material includes an oxide of an element A, an oxide of an element B, an oxide of an element R, and an oxide of an element M;
the element A is indium (In);
the element B is gallium (Ga);
the element R is terbium (Tb);
the element M is tantalum (Ta); and
in the above-mentioned oxide target material, atomic molar ratios of the elements A, B, R and M in the oxide target material are x, y, z and m, respectively, where x=0.74, y=0.24, z=0.006, and m=0.014.

In a preparation method of the oxide target material, powders of indium oxide (In₂O₃), gallium oxide (Ga₂O₃), terbium oxide (Tb₄O₇), and tantalum oxide (Ta₂O₅) were respectively weighed according to an atomic molar ratio of In:Ga:Tb:Ta=0.74:0.24:0.006:0.014, with a total powder weight of 3 kg. The rest steps were the same as those described in the preparation method of Embodiment 16.

### Embodiment 20

An oxide target material includes an oxide of an element A, an oxide of an element B, an oxide of an element R, and an oxide of an element M;
the element A is indium (In);
the element B is zinc (Zn);
the element R is praseodymium (Pr);
the element M is scandium (Sc); and
in the above-mentioned oxide target material, atomic molar ratios of the elements A, B, R and M in the oxide target material are x, y, z and m, respectively, where x=0.65, y=0.32, z=0.015, and m=0.015.

In a preparation method of the oxide target material, powders of indium oxide (In₂O₃), zinc oxide (ZnO), praseodymium oxide (Pr₆O₁₁), and scandium oxide (Sc₂O₃) were respectively weighed according to an atomic molar ratio of In:Zn:Pr:Sc=0.65:0.32:0.015:0.015, with a total powder weight of 3 kg. The rest steps were the same as those described in the preparation method of Embodiment 16.

### Embodiment 21

An oxide target material includes an oxide of an element A, an oxide of an element B, an oxide of an element R, and an oxide of an element M;
the element A is indium (In);
the element B is zinc (Zn);
the element R is praseodymium (Pr);
the element M is titanium (Ti); and
in the above-mentioned oxide target material, atomic molar ratios of the elements A, B, R and M in the oxide target material are x, y, z and m, respectively, where x=0.65, y=0.32, z=0.012, and m=0.018.

In a preparation method of the oxide target material, powders of indium oxide (In₂O₃), zinc oxide (ZnO), praseodymium oxide (Pr₆O₁₁), and titanium oxide (TiO₂) were respectively weighed according to an atomic molar ratio of In:Zn:Pr:Ti=0.65:0.32:0.012:0.018, with a total powder weight of 3 kg. The rest steps were the same as those described in the preparation method of Embodiment 16.

### Embodiment 22

An oxide target material includes an oxide of an element A, an oxide of an element B, an oxide of an element R, and an oxide of an element M;
the element A is indium (In);
the element B is zinc (Zn);
the element R is terbium (Tb);
the element M is silicon (Si); and
in the above-mentioned oxide target material, atomic molar ratios of the elements A, B, R and M in the oxide target material are x, y, z and m, respectively, where x=0.76, y=0.23, z=0.005, and m=0.005.

In a preparation method of the oxide target material, powders of indium oxide (In₂O₃), zinc oxide (ZnO), terbium oxide (Tb₄O₇), and silicon dioxide (SiO₂) were respectively weighed according to an atomic molar ratio of In:Zn:Tb:Si=0.76:0.23:0.005:0.005, with a total powder weight of 3 kg. The rest steps were the same as those described in the preparation method of Embodiment 16.

### Embodiment 23

An oxide target material includes an oxide of an element A, an oxide of an element B, an oxide of an element R, and an oxide of an element M;
the element A is indium (In);
the element B is zinc (Zn);
the element R is terbium (Tb);
the element M is tantalum (Ta); and
in the above-mentioned oxide target material, atomic molar ratios of the elements A, B, R and M in the oxide target material are x, y, z and m, respectively, where x=0.8, y=0.18, z=0.008, and m=0.012.

In a preparation method of the oxide target material, powders of indium oxide (In₂O₃), zinc oxide (ZnO), terbium oxide (Tb₄O₇), and tantalum oxide (Ta₂O₅) were respectively weighed according to an atomic molar ratio of In:Zn:Tb:Ta=0.8:0.18:0.008:0.012, with a total powder weight of 3 kg. The rest steps were the same as those described in the preparation method of Embodiment 16.

### Embodiment 24

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:1;
the element R is praseodymium (Pr);
the element M is scandium (Sc); and
in the above-mentioned oxide target material, atomic molar ratios of the elements A, B, R and M in the oxide target material are x, y, z and m, respectively, where x=0.62, y=0.36, z=0.015, and m=0.005.

In a preparation method of the oxide target material, powders of indium oxide (In₂O₃), gallium oxide (Ga₂O₃), zinc oxide (ZnO), praseodymium oxide (Pr₆O₁₁), and scandium oxide (Sc₂O₃) were respectively weighed according to an atomic molar ratio of In: Ga: Zn: Pr: Sc=0.62:0.18:0.18:0.015:0.005, with a total powder weight of 3 kg. The rest steps were the same as those described in the preparation method of Embodiment 16.

### Embodiment 25

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:1;
the element R is terbium (Tb);
the element M is titanium (Ti); and
in the above-mentioned oxide target material, atomic molar ratios of the elements A, B, R and M in the oxide target material are x, y, z and m, respectively, where x=0.65, y=0.32, z=0.02, and m=0.01.

In a preparation method of the oxide target material, powders of indium oxide (In₂O₃), gallium oxide (Ga₂O₃), zinc oxide (ZnO), terbium oxide (Tb₄O₇), and titanium oxide (TiO₂) were respectively weighed according to an atomic molar ratio of In:Ga:Zn:Tb:Ti=0.65:0.16:0.16:0.02:0.01, with a total powder weight of 3 kg. The rest steps were the same as those described in the preparation method of Embodiment 16.

### Embodiment 26

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:6;
the element R is praseodymium (Pr);
the element M is silicon (Si); and
in the above-mentioned oxide target material, atomic molar ratios of the elements A, B, R and M in the oxide target material are x, y, z and m, respectively, where x=0.76, y=0.21, z=0.016, and m=0.014.

In a preparation method of the oxide target material, powders of indium oxide (In₂O₃), gallium oxide (Ga₂O₃), zinc oxide (ZnO), praseodymium oxide (Pr₆O₁₁), and silicon dioxide (SiO₂) were respectively weighed according to an atomic molar ratio of In:Ga:Zn:Pr:Si=0.76:0.03:0.18:0.016:0.014, with a total powder weight of 3 kg. The rest steps were the same as those described in the preparation method of Embodiment 16.

### Embodiment 27

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:4;
the element R is terbium (Tb);
the element M is tantalum (Ta); and
in the above-mentioned oxide target material, atomic molar ratios of the elements A, B, R and M in the oxide target material are x, y, z and m, respectively, where x=0.76, y=0.22, z=0.008, and m=0.012.

In a preparation method of the oxide target material, powders of indium oxide (In₂O₃), gallium oxide (Ga₂O₃), zinc oxide (ZnO), terbium oxide (Tb₄O₇), and tantalum oxide (Ta₂O₅) were respectively weighed according to an atomic molar ratio of In:Ga:Zn:Tb:Ta=0.76:0.044:0.176:0.008:0.012, with a total powder weight of 3 kg. The rest steps were the same as those described in the preparation method of Embodiment 16.

### Embodiment 28

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:3;
the element R is terbium (Tb);
the element M is antimony (Sb); and
in the above-mentioned oxide target material, atomic molar ratios of the elements A, B, R and M in the oxide target material are x, y, z and m, respectively, where x=0.85, y=0.12, z=0.015, and m=0.015.

In a preparation method of the oxide target material, powders of indium oxide (In₂O₃), gallium oxide (Ga₂O₃), zinc oxide (ZnO), terbium oxide (Tb₄O₇), and antimony oxide (Sb₂O₃) were respectively weighed according to an atomic molar ratio of In:Ga:Zn:Tb:Sb=0.85:0.03:0.09:0.015:0.015, with a total powder weight of 3 kg. The rest steps were the same as those described in the preparation method of Embodiment 16.

### Embodiment 29

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:2;
the element R is praseodymium (Pr);
the element M is antimony (Sb); and
in the above-mentioned oxide target material, atomic molar ratios of the elements A, B, R and M in the oxide target material are x, y, z and m, respectively, where x=0.76, y=0.21, z=0.012, and m=0.018.

In a preparation method of the oxide target material, powders of indium oxide (In₂O₃), gallium oxide (Ga₂O₃), zinc oxide (ZnO), praseodymium oxide (Pr₆O₁₁), and antimony oxide (Sb₂O₃) were respectively weighed according to an atomic molar ratio of In:Ga:Zn:Pr:Sb=0.76:0.07:0.14:0.012:0.018, with a total powder weight of 3 kg. The rest steps were the same as those described in the preparation method of Embodiment 16.

### Embodiment 30

An oxide target material includes an oxide of an element A, an oxide of an element B, an oxide of an element R, and an oxide of an element M;
the element A is indium (In);
the element B includes gallium (Ga) and zinc (Zn); a molar ratio of gallium to zinc is 1:6;
the element R is terbium (Tb);
the element M is antimony (Sb); and
in the above-mentioned oxide target material, atomic molar ratios of the elements A, B, R and M in the oxide target material are x, y, z and m, respectively, where x=0.76, y=0.21, z=0.012, and m=0.018.

In a preparation method of the oxide target material, powders of indium oxide (In₂O₃), gallium oxide (Ga₂O₃), zinc oxide (ZnO), terbium oxide (Tb₄O₇), and antimony oxide (Sb₂O₃) were respectively weighed according to an atomic molar ratio of In:Ga:Zn:Tb:Sb=0.76:0.03:0.18:0.012:0.018, with a total powder weight of 3 kg. The rest steps were the same as those described in the preparation method of Embodiment 16.

### Comparative Embodiment 1

Compared with Embodiment 2, in this comparative embodiment, the atomic molar ratio In:Ga:Zn:Pr=0.64:0.11:0.22:0.015 of the metal elements in the oxide target material remained unchanged, but the oxide of the element M was not added in this comparative embodiment, and other parameters and preparation processes remained the same as those described Embodiment 2.

### Comparative Embodiment 2

The difference between this comparative embodiment and Embodiment 2 was that atomic molar ratios of elements A, B, R, and M in an oxide target material are x, y, z, and m, respectively, where x=0.64, y=0.33, z-0.015, and m=0.03. Other parameters and preparation processes remained the same as those described Embodiment 2.

### Comparative Embodiment 3

The difference between this comparative embodiment and Embodiment 2 is that atomic molar ratios of elements A, B, R, and M in an oxide target material are x, y, z, and m, respectively, where x=0.64, y=0.33, z=0.015, and m=0.05. Other parameters and preparation processes remained the same as those described Embodiment 2.

### Comparative Embodiment 4

The difference between this comparative embodiment and Embodiment 11 is that there was no process for a second sintering temperature in this comparative embodiment, only a first sintering temperature was maintained. That is, the specific method of step 3 in this comparative embodiment is:

Step 3: The temperature was raised from 700° C. to a first sintering temperature of 1250° C. at a first heating rate of 1° C./min, and the first sintering temperature was kept unchanged for 10 h in a gas environment with an oxygen content of 20-30% in the air; and the first sintering temperature of 1250° C. was continued to be kept unchanged for 30 h in a gas environment with an oxygen content of 40-50% in the air.

Other parameters and preparation processes remained the same as those described Embodiment 11.

### Comparative Embodiment 5

The difference between Comparative Embodiment 5 and Embodiment 11 is that a holding time of a first sintering temperature in Comparative Embodiment 5 is only 5 h each time, and a total holding time of the first sintering temperature is 20 h. That is, the specific method of step 3 in this comparative embodiment is:

Step 3: The temperature was raised from 700° C. to a first sintering temperature of 1250° C. at a first heating rate of 1° C./min, and the first sintering temperature was kept unchanged for 5 h in a gas environment with an oxygen content of 20-30% in the air. Then, the temperature was raised to a second sintering temperature of 1420° C. at a second heating rate of 8° C./min, and the second sintering temperature was kept unchanged for 30 min in a gas environment with an oxygen content of 40-50% in the air. After that, the temperature was lowered to the first sintering temperature of 1250° C. at a first cooling rate of 3° C./min, and the first sintering temperature was kept unchanged for 5 h in the gas environment with the oxygen content of 40-50% in the air.

The temperature was rapidly raised to a second sintering temperature of 1460° C. at the heating rate of 8° C./min, and the second sintering temperature was kept unchanged for 30 min in the gas environment with the oxygen content of 40-50% in the air; and then, the temperature was lowered to the first sintering temperature of 1250° C. at the cooling rate of 3° C./min, and the first sintering temperature was kept unchanged for 5 h in the gas environment with the oxygen content of 40-50% in the air.

The temperature was rapidly raised to a second sintering temperature of 1500° C. at the heating rate of 8° C./min, and the second sintering temperature was kept unchanged for 30 min in a gas environment with an oxygen content of 60-70% in the air; and then, the temperature was lowered to the first sintering temperature of 1250° C. at the cooling rate of 3° C./min, and the first sintering temperature was kept unchanged for 5 h in the gas environment with the oxygen content of 40-50% in the air.

Other parameters and preparation processes remained the same as those described Embodiment 11.

### Comparative Embodiment 6

The difference between Comparative Embodiment 6 and Embodiment 11 is that a holding time of a second sintering temperature in Comparative Embodiment 6 is only 5 h each time, and a total holding time of the second sintering temperature is 15 h. That is, the specific method of step 3 in this comparative embodiment is:

Step 3: The temperature was raised from 700° C. to a first sintering temperature of 1250° C. at a first heating rate of 1° C./min, and the first sintering temperature was kept unchanged for 10 h in a gas environment with an oxygen content of 20-30% in the air. Then, the temperature was raised to a second sintering temperature of 1420° C. at a second heating rate of 8° C./min, and the second sintering temperature was kept unchanged for 5 h in a gas environment with an oxygen content of 40-50% in the air. After that, the temperature was lowered to the first sintering temperature of 1250° C. at a first cooling rate of 3° C./min, and the first sintering temperature was kept unchanged for 10 h in the gas environment with the oxygen content of 40-50% in the air.

The temperature was rapidly raised to a second sintering temperature of 1460° C. at the heating rate of 8° C./min, and the second sintering temperature was kept unchanged for 5 h in a gas environment with the oxygen content of 60-70% in the air; and then, the temperature was lowered to the first sintering temperature of 1250° C. at the cooling rate of 3° C./min, and the first sintering temperature was kept unchanged for 10 h in the gas environment with the oxygen content of 60-70% in the air.

The temperature was rapidly raised to a second sintering temperature of 1500° C. at the heating rate of 8° C./min, and the second sintering temperature was kept unchanged for 5 h in the gas environment with the oxygen content of 60-70% in the air; and then, the temperature was lowered to the first sintering temperature of 1250° C. at the cooling rate of 3° C./min, and the first sintering temperature was kept unchanged for 10 h in the gas environment with the oxygen content of 60-70% in the air.

Other parameters and preparation processes remained the same as those described Embodiment 11.

### Comparative Embodiment 7

The difference between Comparative Embodiment 7 and Embodiment 11 is that repeated sintering processes are not carried out in this comparative embodiment, a total holding time of a first sintering temperature is 20 h, and a holding time of a second sintering temperature is 0.5 h. That is, the specific method of step 3 in this comparative embodiment is:

Step 3: The temperature was raised from 700° C. to a first sintering temperature of 1250° C. at a first heating rate of 1° C./min, and the first sintering temperature was kept unchanged for 10 h in a gas environment with an oxygen content of 20-30% in the air. Then, the temperature was raised to a second sintering temperature of 1420° C. at a second heating rate of 8° C./min, and the second sintering temperature was kept unchanged for 30 min in a gas environment with an oxygen content of 40-50% in the air. After that, the temperature was lowered to the first sintering temperature of 1250° C. at a first cooling rate of 3° C./min, and the first sintering temperature was kept unchanged for 10 h in the gas environment with the oxygen content of 40-50% in the air.

Other parameters and preparation processes remained the same as those described Embodiment 11.

### Target Material Performance Test

By adopting the conventional characterization method, a resistivity of a target material block was measured by four-probe equipment. The target material was subjected to wet chemical polishing and its grain size was measured using a crystal phase microscope. A relative density of the target material was measured by a drainage method, and the element distribution thereof was measured using a scanning electron microscope. The resistivity, grain size, relative density and element distribution of each of the oxide target materials prepared in Embodiments 1-30 and Comparative Embodiments 1-7 were tested. The test results are shown in Table 1.

TABLE 1

| | Resistivity | Grain size | Relative | Element |
|---|---|---|---|---|
| Embodiment | (mΩ · cm) | (μm) | density | distribution |
| Embodiment 1 | 8.2 | 4.2 | 99.20% | uniform |
| Embodiment 2 | 8.5 | 4.5 | 99.30% | uniform |
| Embodiment 3 | 9.1 | 3.8 | 98.50% | uniform |
| Embodiment 4 | 9.5 | 3.5 | 98.90% | uniform |
| Embodiment 5 | 8.5 | 3.6 | 99.30% | uniform |
| Embodiment 6 | 8.3 | 3.8 | 99.40% | uniform |
| Embodiment 7 | 7.5 | 4.1 | 99.10% | uniform |
| Embodiment 8 | 2.2 | 4.5 | 98.50% | uniform |
| Embodiment 9 | 1.5 | 4.6 | 99.50% | uniform |
| Embodiment 10 | 5.6 | 3.8 | 99.40% | uniform |
| Embodiment 11 | 5.2 | 3.4 | 99.20% | uniform |
| Embodiment 12 | 4.8 | 3.2 | 98.80% | uniform |
| Embodiment 13 | 1.6 | 4.2 | 99.20% | uniform |
| Embodiment 14 | 1.1 | 4.5 | 99.40% | uniform |
| Embodiment 15 | 3.5 | 3.3 | 98.70% | uniform |
| Embodiment 16 | 3.2 | 4.3 | 99.50% | uniform |
| Embodiment 17 | 2.3 | 4.5 | 99.10% | uniform |
| Embodiment 18 | 1.8 | 4.1 | 98.70% | uniform |
| Embodiment 19 | 3.4 | 4.5 | 98.80% | uniform |
| Embodiment 20 | 4.5 | 4.1 | 99.30% | uniform |
| Embodiment 21 | 4.7 | 3.2 | 99.20% | uniform |
| Embodiment 22 | 3.5 | 3.4 | 99.40% | uniform |
| Embodiment 23 | 2.4 | 3.1 | 98.70% | uniform |
| Embodiment 24 | 5.2 | 3.4 | 99.30% | uniform |
| Embodiment 25 | 5.6 | 3.1 | 99.20% | uniform |
| Embodiment 26 | 3.1 | 3.6 | 99.00% | uniform |
| Embodiment 27 | 3.2 | 3.5 | 98.80% | uniform |
| Embodiment 28 | 2.4 | 3.2 | 99.40% | uniform |
| Embodiment 29 | 2.5 | 3.6 | 99.20% | uniform |
| Embodiment 30 | 2.3 | 3.7 | 98.80% | uniform |
| Comparative | 8.2 | 14.6 | 98.20% | nonuniform |
| Embodiment 1 | | | | |
| Comparative | 14.2 | 4.1 | 95.50% | uniform |
| Embodiment 2 | | | | |
| Comparative | 45.4 | 5.4 | 92.10% | uniform |
| Embodiment 3 | | | | |
| Comparative | 105.1 | 4.5 | 82.20% | nonuniform |
| Embodiment 4 | | | | |
| Comparative | 65.2 | 3.4 | 92.50% | nonuniform |
| Embodiment 5 | | | | |
| Comparative | 5.5 | 15.4 | 99.40% | nonuniform |
| Embodiment 6 | | | | |
| Comparative | 45.6 | 4.3 | 90.10% | uniform |
| Embodiment 7 | | | | |

It can be seen from Table 1 that the oxide target materials prepared in Embodiments 1-30 of the present disclosure are all lower in resistivity, extremely small in grain size, higher in relative density, and uniform in element distribution.

From the comparison between Comparative Embodiment 1 and Embodiment 2, it can be seen that the relative density of the oxide target material prepared without adding the oxide of the element M is reduced, the grain size thereof is significantly increased, and the element distribution of the target material is not uniform.

From the comparison between Comparative Embodiments 2-3 and Embodiment 2, it can be seen that when the addition amount of the oxide of the element M is too high, the resistivity of the oxide target material increases to a certain extent, the grain size thereof is smaller, but the relative density thereof decreases to a certain extent.

From the comparison between Comparative Embodiment 4 and Embodiment 11, it can be seen that the oxide target material prepared by the sintering procedure that only maintains the first sintering temperature shows a significant increase in resistivity (105.1 mΩ·cm) and a significant decrease in density (only 82.2%), and is nonuniform in element distribution, which indicates that the oxide target material prepared in Comparative Embodiment 4 is not fully sintered and thus cannot meet the practical application requirements.

From the comparison between Comparative Embodiment 5 and Embodiment 11, it can be seen that when the holding time of the first sintering temperature is insufficient, the prepared oxide target material shows an increases in resistivity (65.2 mΩ·cm) and a decrease in relative density (92.5%), and is nonuniform in element distribution, which indicates that the oxide target material prepared in Comparative Embodiment 5 is not fully sintered and thus cannot meet the practical application requirements.

From the comparison between Comparative Embodiment 6 and Embodiment 11, it can be seen that when the holding time of the second sintering temperature is too long, the prepared oxide target material is equivalent in resistivity (5.5 mΩ·cm), higher in relative density (99.4%), but nonuniform in element distribution, and the grain size of the target material is significantly increased to 15.4 μm, which indicates that the target material prepared in Comparative Embodiment 6 is over-sintered and thus cannot meet the practical application requirements.

From the comparison between Comparative Embodiment 7 and Embodiment 11, it can be seen that the oxide target material prepared without being subjected to repeated sintering shows an increase in resistivity (45.6 mΩ·cm) and a decrease in relative density (90.1%), which indicates that the target material prepared in Comparative Embodiment 7 is not fully sintered and thus cannot meet the practical application requirements.

The above-mentioned embodiments are only some of the embodiments of the present disclosure, and their descriptions are more specific and detailed, but they cannot be construed as limiting the patent scope of the present disclosure. It should be pointed out that for those of ordinary skill in the art, some variations and improvements without departing from the concept of the present disclosure can also be made, which shall also be regarded as the protection scope of the present disclosure, Therefore, the protection scope of the present disclosure shall be as defined in the appended claims.

What is claimed is:

1. An oxide target material, comprising an oxide of an element A, an oxide of an element B, an oxide of an element R, and an oxide of an element M, wherein
the element A is indium;
the element B is selected from the group consisting of gallium, zinc, and tin, or a combination of two or more thereof;
the element R is selected from the group consisting of cerium, praseodymium, ytterbium, dysprosium, and terbium, or a combination of two or more thereof; and
the element M is selected from the group consisting of scandium, silicon, titanium, tantalum, germanium, and antimony, or a combination of two or more thereof.

2. The oxide target material according to claim 1, wherein atomic molar ratios of the elements A, B, R and M in the oxide target material are x, y, z and m, respectively, wherein 0.6≤x≤0.9994, 0≤y≤0.3994, 0.0005≤z≤0.05, 0.001<m<0.02, and x+y+z+m=1.

3. The oxide target material according to claim 2, wherein 0.76≤x≤0.9994, and 0.005≤m≤0.015.

4. The oxide target material according to claim 1, wherein a resistivity of the oxide target material is less than 10 mΩ·cm, and a relative density of the oxide target material is 98.5% or more.

5. The oxide target material according to claim 1, wherein oxide target material grains have a maximum grain size of less than 8 μm.

6. A preparation method of the oxide target material according to claim 1, comprising following steps:
step 1: pressing powders into a target material blank;
step 2: drying the target material blank and then performing debinding treatment;
step 3: continuing to heat the debinded target material blank up to a first sintering temperature at a first heating rate in a gas environment for sintering, then continuing to heat the debinded target material blank up to a second sintering temperature at a second heating rate for sintering, and finally cooling down to the first sintering temperature at a first cooling rate to continue sintering;
step 4: after sintering is completed, cooling down to a room temperature at a second cooling rate in the gas environment to obtain a sintered target material; and
step 5: machining and bonding the sintered target material.

7. The preparation method of the oxide target material according to claim 6, wherein the debinding treatment in step 2 comprises firstly heating the target material blank up to 600-800° C. at a heating rate of 0.2-1° C./min; and debinding lasts for 50-100 h.

8. The preparation method of the oxide target material according to claim 6, wherein the first heating rate is 0.1-5° C./min, and the first sintering temperature is 1200-1400° C.; and the second heating rate is 5-10° C./min, and the second sintering temperature is 1410-1600° C.

9. The preparation method of the oxide target material according to claim 6, wherein the sintering process of step 3 is repeated for a plurality of times, and the first sintering temperature, the second sintering temperature, the first heating rate, the second heating rate and the first cooling rate are the same or different during the repeated processes.

10. The preparation method of the oxide target material according to claim 6, wherein each holding time at the first sintering temperature is 10-250 h; and each holding time at the second sintering temperature is 10-60 min.
